(19) United States
(12) Patent Application Publication
(10) Pub. No.: US 2008/0120530 A1
(43) Pub. Date: May 22, 2008

(54) Transceiver puncture circuit of wireless communication system

(76) Inventors: Yu-Min Chuang, Hsinchu City (TW); Fu-Min Yeh, Taoyuan City (TW); Juinn-Horng Deng, Pingjhen City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/603,304

(22) Filed: Nov. 22, 2006

(51) Int. Cl. H03M 13/03

(52) U.S. Cl. 714/790

(57) ABSTRACT

The present invention relates to a transceiver puncture circuit of wireless communication system, which is amounted with a control circuit and a clipper module, the puncture module couples to a coding unit of the transceiver. The control circuit bases on a fixed clock signal, results in an enable signal to the coding unit and also results in a selecting signal to the clipper circuit; the coding unit codes an input data as a coding data and transfers the coding data to the clipper module, the coding data comprises a plurality of bit data; the clipper module selects the partial bit data of the bit data according to the selecting signal, and then results in a output data according to the fixed clock signal. Therefore, it achieves that the control circuit synchronously controls a clipper module and a coding unit of the transceiver for improving the deal effect of the transceiver.

### BACKGROUND OF THE INVENTION

1. Field of the Invention

The present invention relates to a communication system and, more particularly, to a transceiver puncture circuit of wireless communication system, which is capable of improving the dealing effect of the transceiver.

2. Description of Related Art

Currently, the communication system had stepped into the generation of wireless communication system. To mention about the data transferring, the transceiver of the communication system has to transfer an input data into a coding data from a data processing circuit, and select the partial coding content of the coding data as an output data in order to output to a RF circuit. Please take reference of FIG. 1, it is a figure of prior art of a transceiver of wireless communication system. As shown in the figure, the transceiver of prior art comprises an scrambling unit 12, a coding unit 14, a clipper 16, a register 18, a map unit 20, a Fast Fourier transform (FFT) 22, a Digital-to-Analog Converter (DAC) 24 and a RF circuit 26.

Scrambling unit 12 is to scramble an input data and transfer the scrambled input data coding unit 14. Coding unit 14 is a coding data of the input data after agitation, and to transfer the coding data to clipper 16, wherein that the coding data comprises a plurality of bit data; clipper 16 selects some partial coding data as an output data and transfers the output data to register 18, register 18 transfers the output data to map unit 20 according to the clock signal of the transceiver, wherein that clipper 16 determines the selecting method of the coding data according to the output format of coding unit 14, for example: coding unit 14 output 3 bit data to clipper 16 in the same time, which is to make clipper 16 select 2 bit data of the coding data. Map unit 20 transfers the map-completed output data to Fast Fourier transform 22. Fast Fourier transform 22 transfers the output data after completing the Fast Fourier transform to Digital-to-Analog Converter 24. Digital-to-Analog Converter 24 converts the output data to an analog signal and transfers to RF circuit 26. RF circuit 26 transfers the analog signal to a transceiver.

Clipper 16 of prior art achieves the phase delay by a plurality of latch-up circuits and converts the parallel data into series data, for example: as shown in FIG. 2, clipper 16 of transceiver of prior art amounts a first latch-up circuit 162, a second latch-up circuit 164, a third latch-up circuit 166, a fourth latch-up circuit 168, a fifth latch-up circuit 170, a sixth latch-up circuit 172 and a multiplexer 174. Clipper 16 converts the parallel inputted coding data into the series outputted selecting data, wherein that first latch-up circuit 162, a second latch-up circuit 164 and a third latch-up circuit 166 respectively save one bit data. When clipper 16 is in the first clock cycle, output the bit data of first latch-up circuit 162 to multiplexer 174, the bit data of second latch-up circuit 164 to fourth latch-up circuit 168, the bit data of third latch-up circuit 166 to fifth latch-up circuit 170. When clipper 16 is in the second clock cycle, output the bit data, which outputs from fourth latch-up circuit 168 to second latch-up circuit 164, to multiplexer 174, the bit data, which outputs from fifth latch-up circuit 170 to third latch-up circuit 166, to sixth latch-up circuit 172. When clipper 16 is in the third clock cycle, output the bit data, which outputs from sixth latch-up circuit 172 to third latch-up circuit 166, to multiplexer 174. Multiplexer 174 output the bit data respectively to register 18.

The outputted data of clipper 16 of prior art comprises 3 bit data in each clock cycle, therefore clipper 16 delays and outputs a series data to register 18 by using six latch-up circuits. When the input data of clipper 16 is over 3 bit data, clipper 16 has to use over six latch-up circuits in order to delay and output the bit data to register 18, it results in arranging more latch-up circuits and increasing the clock frequency of latch-up circuit to make clipper 16 output more bit data into series data, thus, it will increase the circuit area of clipper 16 and power consuming, moreover, to increase the power consuming of register 18. In addition that the increasing input data will also increase the output data of clipper 16 and then further to increase the capacity of register in order to contain more bit data, therefore, with the increasing of the capacity, it also results the volume increasing of the register.

Therefore, the present invention is to provide an improved transceiver clipper circuit of wireless communication system, which comprises using a fixed clock signal and data transferring rate to control the coding unit of a clipper module and the transceiver in order to decrease the arrangement of latch-up circuits and registers further to decrease the power consuming.

### SUMMARY OF THE INVENTION

The object of the present invention is to provide a transceiver puncture circuit of wireless communication system comprising a control circuit, which bases on a fixed clock signal and a data transferring rate to result a first enable signal and a selecting signal, a coding unit of the transceiver results in a coding data to a puncture module according to the enable and the fixed clock signal, the puncture module selects the coding data according to said selecting signal and outputs a output data according to the fixed clock signal in order to decrease the arrangement of register and latch-up circuit.

The second object of the present invention is to provide a transceiver puncture circuit of wireless communication system comprising a control circuit, which bases on a fixed clock signal and a data transferring rate to enable a coding unit and then, to select the selecting mode of puncture module in order to decrease the clock differences between the members and further to lower the power consuming.

The present invention is a transceiver puncture circuit of wireless communication system comprising: a control circuit and a puncture module, the control circuit, which bases on a fixed clock signal and transfer a data transferring rate of an input data in order to result a first enable signal and a selecting signal; the puncture module, which couples to a coding unit of the transceiver and the control circuit, the coding unit results in a coding data to the puncture module according to the first enable and said fixed clock signal, the coding data comprises a plurality of bit data, the puncture module selects some partial bit data of the bit data as a output data according to the selecting signal, and outputs the output data bases on the fixed clock signal. On the other hand, the puncture circuit of the present invention further couples to an scrambling unit, which couples to the control circuit and the coding unit, the control circuit results in a second enable signal to the scrambling unit according to the fixed clock signal and the data transferring rate, the scrambling unit scrambles the input date according to the second enable signal, and transfers the scrambled input date to the coding unit.

Other objects, advantages, and novel features of the invention will become more apparent from the following detailed description when taken in conjunction with the accompanying drawings.

### BRIEF DESCRIPTION OF THE DRAWINGS

FIG. 1 is a figure of transceiver of prior art wireless communication system.

FIG. 2 is a block diagram of-clipper of prior art transceiver.

FIG. 3 is a block diagram of transceiver of present invention.

FIG. 4A is the state of one preferred embodiment of data coding of present invention.

FIG. 4B is a flowchart of one preferred embodiment of data coding of present invention.

FIG. 5A is the state of another preferred embodiment of data coding of present invention.

FIG. 5B is a flowchart of another preferred embodiment of data coding of present invention.

FIG. 6 is a block diagram of control circuit of present invention.

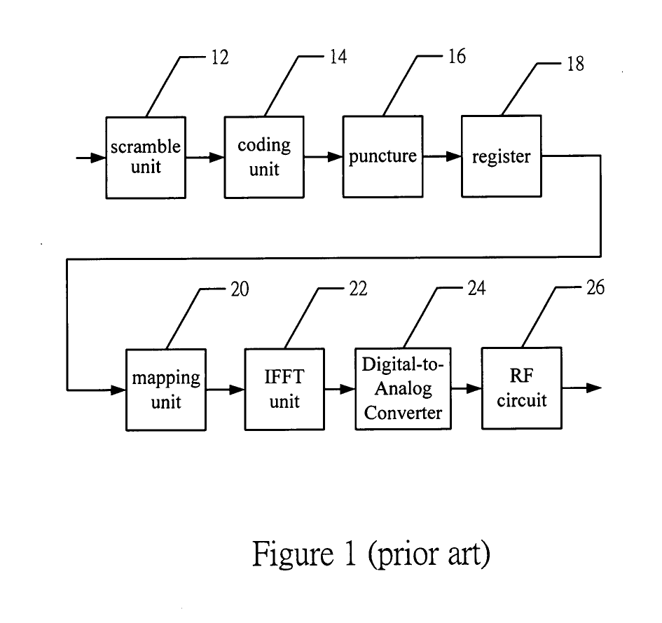

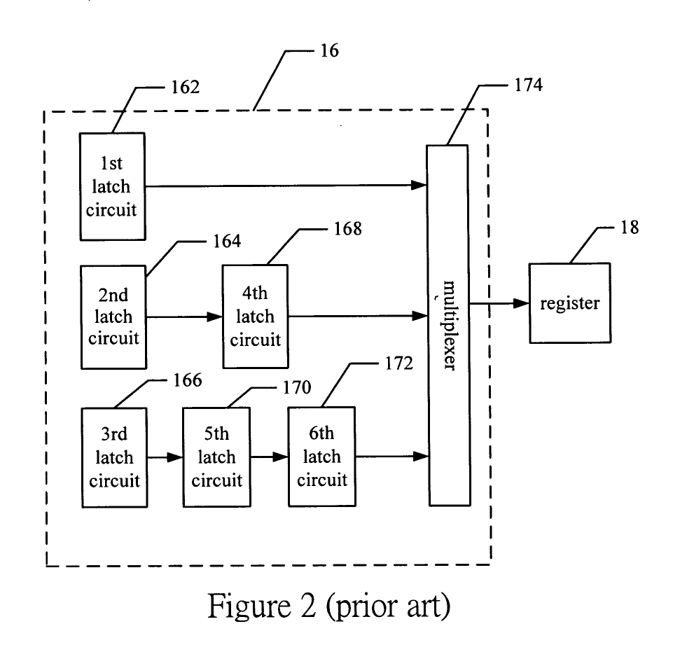

### DETAILED DESCRIPTION OF THE PREFERRED EMBODIMENT

The present invention is a transceiver puncture circuit of wireless communication system, which provides a novel clipper circuit comprising: a control circuit and a clipper module, the control circuit bases on a fixed clock signal and transfer a data transferring rate of an input data in order to result a first enable signal and a selecting signal; the puncture module couples to a coding unit of the transceiver, the coding unit codes an input data according to the enable signal and the fixed clock signal, therefore results in a coding data to the clipper module, wherein the coding data comprises a plurality of bit data, the puncture module selects some partial bit data of the bit data according to the selecting signal of the control circuit, therefore results in a output data, and outputs the output data bases on the fixed clock signal.

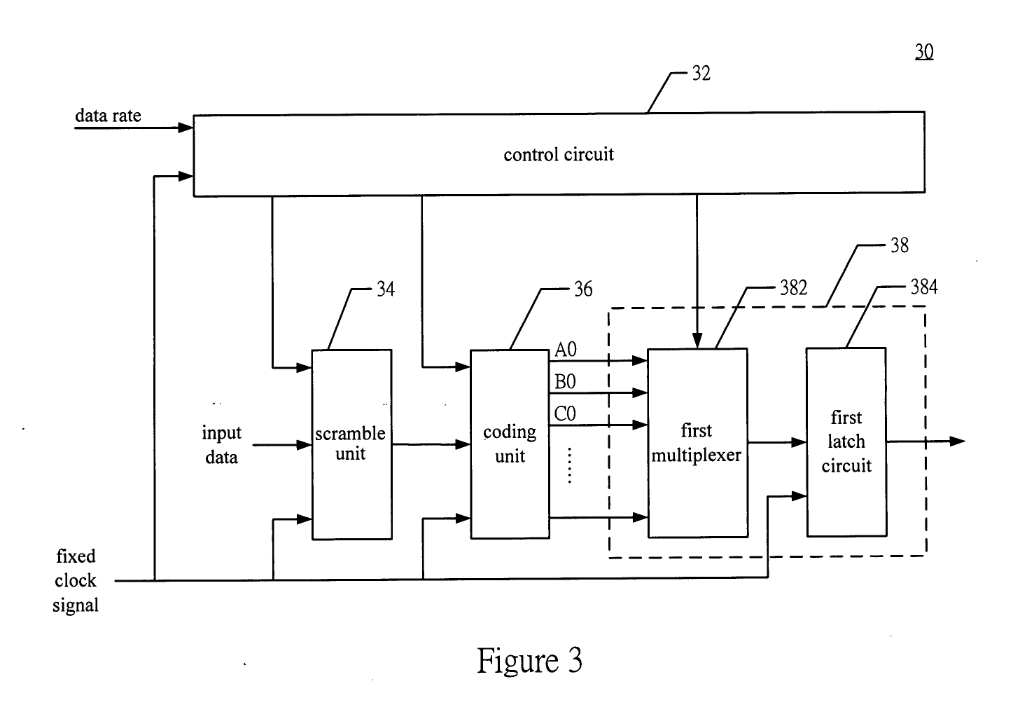

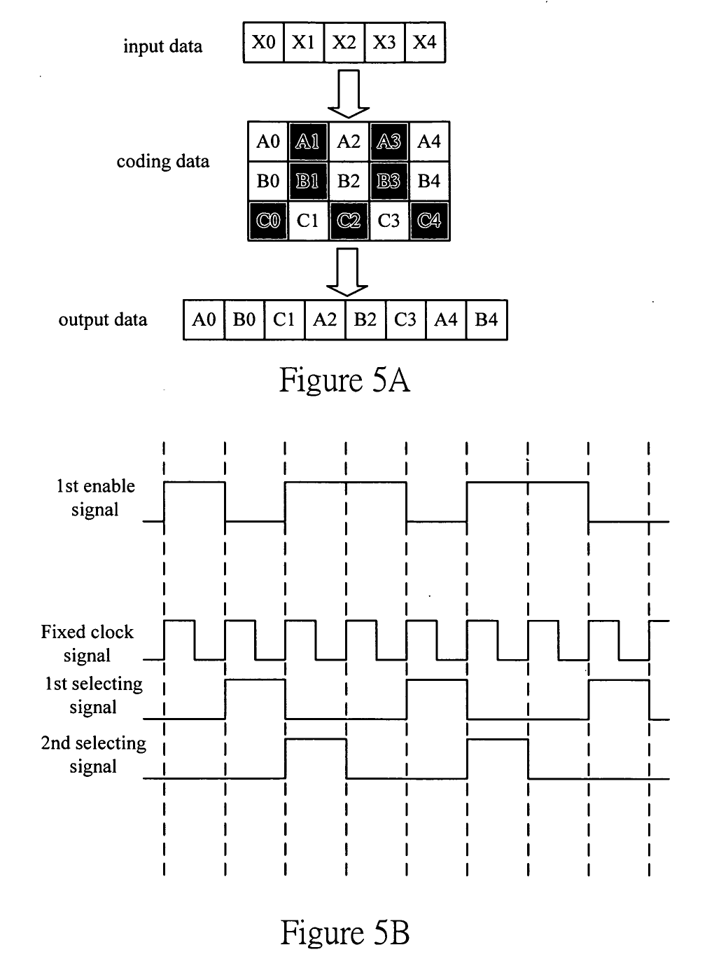

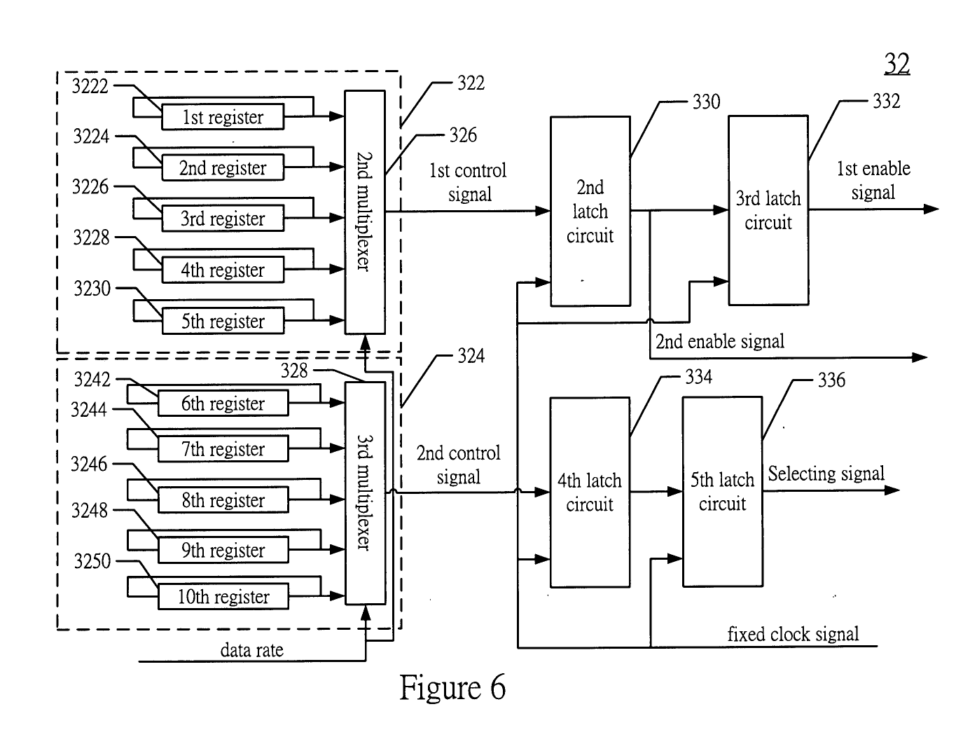

With reference to FIG. 3, there is shown that the transceiver of present invention. As shown in the figure, transceiver 30 of the present invention is amounted with a control circuit 32, a scrambling unit 34, a coding unit 36 and a clipper module 38, wherein clipper 38 is amounted with a first multiplexer 382 and a first latch-up circuit 384, and first latch-up circuit 384 is a flip-flop. Control circuit 32 results a first enable signal, a second enable signal and a third enable signal according to a fixed clock signal a data transferring rate, and scrambling unit 34 scrambles an input data of transceiver 30 according to the fixed clock signal and the second enable signal and then transfers the scrambled input data to coding unit 36. Coding unit 36 codes the scrambled input data according to the first enable signal and the fixed clock signal therefore makes coding unit 36 results in a coding data in the same time. In the mean while, coding unit 36 outputs the coding data to first multiplexer 382 of clipper module 38 according to the fixed clock signal.

Wherein, the coding data comprises a plurality of bit data, and coding unit 36 outputs in parallel the bit data to first multiplexer 382 according to the fixed clock signal, for example: when the data coding rate of clipper module 38 is ¾, make coding unit 36 code the input data into a plurality of bit data and output in parallel the bit data to first multiplexer 382 from coding unit 36, wherein, the input data is 3 bit data, the bit data outputted from coding unit 36 is 3×3 bit data. First multiplexer 382 selects and outputs the 4 bit data of the bit data as an output data according to the selecting signal of control circuit 32, and output in sequence the output data to first latch-up circuit 384; first latch-up circuit 384 is the output data outputted from first multiplexer 382 and output the output data according to the fixed clock signal. The operating methods of control circuit 32, coding unit 36 and clipper module 38 are shown at FIG. 5 and FIG. 6, which corresponds to different first enable signal and selecting signal according to different data transferring rates in order to induce coding unit 36 output the coding data to first multiplexer 382 of clipper module 38, and induce first multiplexer 382 select and output the partial bit data of the coding data as the output data to firs latch-up circuit 384.

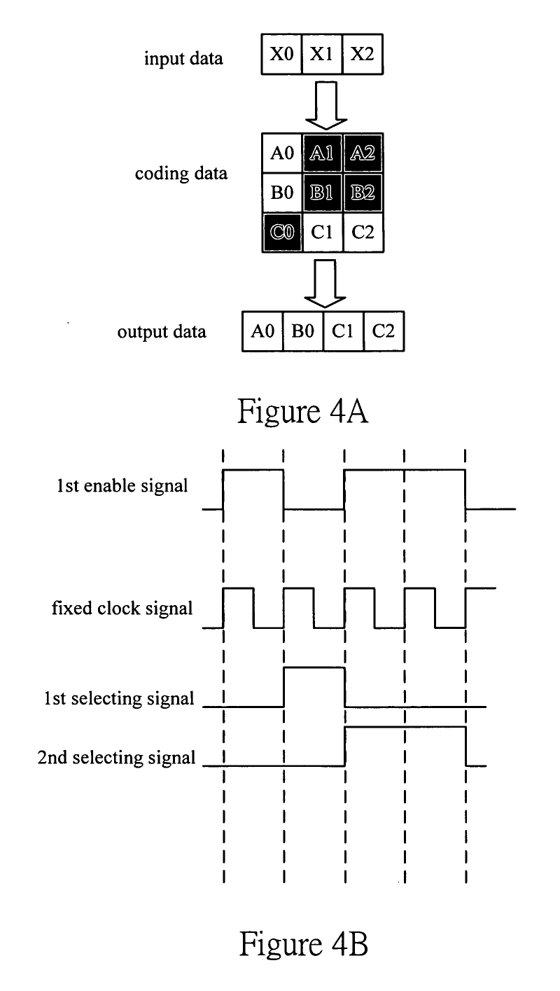

With reference to FIG. 4A, the preferred embodiment of the present invention, as show in the figure that the clipper circuit of present invention comprises control circuit 32, which processes the synchronous control by the data transferring rate and the fixed clock signal for agitating the input data, coding the input data, selecting and outputting the coding data as the output data and synchronous output the output data in the same time. In the present embodiment, the data dealing method of the clipper circuit is making the input data of coding unit 36 as a 3 bit data and the output data of clipper module 38 as a 4 bit data by first enable signal 38 and the selecting signal of control circuit 32, which comprises the data coding rate of 3/4 and the corresponding data transferring rate of 200 MHz or 400 MHz. Wherein, the input data is a three bit data from X0 to X2. Coding unit 36 codes the input data X0 as bit data A0, bit data B0 and bit data C0 of the coding data, Coding unit 36 codes the input data X1 as bit data A1, bit data B1 and bit data C1 of the coding data, Coding unit 36 codes the input data X2 as bit data A2, bit data B2 and bit data C2 of the coding data.

As shown in FIG. 4B, the flowchart of one preferred embodiment of input data and output data of present invention. Clipper module 38 selects and outputs the coding data as a 4 bit output data, wherein the bit data selected and outputted by clipper module 38 are bit data A0, bit data B0, bit data C1 and bit data C2 of the coding data to clipper module 38. When first enable signal is in first clock cycle enable, it is able to make coding unit 36 output bit data A0 to bit data CO to clipper module 38. When first enable signal is in the second clock cycle disenable, it is unable to make coding unit 36 output data to clipper module 38. When first enable signal is in the third clock cycle enable, it is able to make coding unit 36 output bit data A1 to bit data C1 to clipper module 38. When first enable signal is in the fourth clock cycle enable, it is able to make coding unit 36 output bit data A2 to bit data C2 to clipper module 38, wherein the disenable of first enable signal is to provide clipper module 38 select and output one of the bit data, which collects from the former clock cycle.

The selecting signal of clipper module 38 in the present embodiment comprises a first selecting signal and a second selecting signal, when the first selecting signal and the second selecting signal are 0 and 0 in the first clock cycle, and make clipper module 38 select and output bit data A0, when the first selecting signal and the second selecting signal are 1 and 0 in the second clock cycle, and make clipper module 38 select and output bit data B0, when the first selecting signal and the second selecting signal are 0 and 1 in the third clock cycle, and make clipper module 38 select and output bit data C1, when the first selecting signal and the second selecting signal are 1 and 0, and make clipper module 38 select and output bit data C2.

With reference to figure SA, the preferred embodiment of input and out put data of the present invention, as show in the figure that the clipper circuit of present invention is able to use in an input data as a five bit data and a data dealing method of an output data as an eight bit data, which comprises the data coding rate of ⅝ and the corresponding data transferring rate of 480 MHz. Wherein, the input data is from X0 to X4. Coding unit 36 codes the input data X0 as bit data A0 of the coding data to bit data C0, coding unit 36 codes the input data X1 as bit data A1 to bit data C1 of the coding data, coding unit 36 codes the input data X2 as bit data A2 to bit data C2 of the coding data, coding unit 36 codes the input data X3 as bit data A3 to bit data C3 of the coding data, coding unit 36 codes the input data X4 as bit data A4 to bit data C4 of the coding data.

As shown in FIG. 5B, the flowchart of one preferred embodiment of input data and output data of present invention. When first enable signal is in first clock cycle enable, it is able to make coding unit 36 output bit data A0 to bit data C0 to clipper module 38. When first enable signal is in the second clock cycle disenable, it is unable to make coding unit 36 output data to clipper module 38. When first enable signal is in the third clock cycle enable, it is able to make coding unit 36 output bit data A1 to bit data C1 to clipper module 38. When first enable signal is in the fourth clock cycle enable, it is able to make coding unit 36 output bit data A2 to bit data C2 to clipper module 38,

when first enable signal is in the fifth clock cycle disenable, it is able to make coding unit 36 not output data to clipper module 38, when first enable signal is in the sixth clock cycle enable, it is able to make coding unit 36 output bit data A3 to bit data C3 to clipper module 38, the coding unit is in the seventh clock cycle enable, it is able to make coding unit 36 output bit data A4 to bit data C4 to clipper module, when first enable signal is in the eighth clock cycle disenable, it is unable to make coding unit 36 output bit data to clipper module 38.

The selecting signal of clipper module 38 in the present embodiment comprises a first selecting signal and a second selecting signal, when the first selecting signal and the second selecting signal are 0 and 0 in the first clock cycle, and make clipper module 38 select and output bit data A0, when the first selecting signal and the second selecting signal are 1 and 0 in the second clock cycle, and make clipper module 38 select and output bit data B0, when the first selecting signal and the second selecting signal are 0 and 1 in the third clock cycle, and make clipper module 38 select and output bit data C1, when the first selecting signal and the second selecting signal are 0 and 0 in the fourth cycle, and make clipper module 38 select and output bit data A2 according to selecting signal 00, when the first selecting signal and the second selecting signal are 1 and 0 in the fifth clock cycle, and make clipper module select and output bit data B2 according selecting signal 10, when the first selecting signal and the second selecting signal is 01 in the six clock cycle, and make clipper module 38 select and output bit data C3, when the first selecting signal and the second selecting signal are 0 and 0 in the seventh clock cycle, and make clipper module select and output bit data A4, when the first selecting signal and the second selecting signal are 1 and 0 in the eighth clock cycle, and make clipper module select and output bit data B4.

According to the mention above, the clipper circuit of the present invention only has to amount a plurality of latch-up circuit in the control circuit 32 in order to make different between first enable signal and second enable signal without making clipper module 36 amount with a plurality of latch-up circuit to delay the output data, which is able to correspond to various data coding rate, moreover, the present invention use not only the data coding rate of ¾ and ⅝, which are mentioned above, but also apply with other data coding rate, and the different data coding rate respectively corresponds to different data transferring rate, for example: if the data transferring rate is 53.8 MHz or 106.7 MHz, the corresponding data coding rate is ⅓, if the data transferring rate is 480 MHz, the corresponding data coding rate is ¾, if the data transferring rate is 200 MHz or 400 MHz, the corresponding data coding rate is ⅝.

With reference to FIG. 3, there is shown that the transceiver of present invention. As shown in the figure, transceiver 30 of the present invention is amounted with a control circuit 32, a scrambling unit 34, a coding unit 36 and a clipper module 38, wherein clipper 38 is amounted with a first multiplexer 382 and a first latch-up circuit 384, and first latch-up circuit 384 is a flip-flop. Control circuit 32 results a first enable signal, a second enable signal and a third enable signal according to a fixed clock signal a data transferring rate, and scrambling unit 34 scrambles an input data of transceiver 30 according to the fixed clock signal and the second enable signal and then transfers the scrambled input data to coding unit 36. Coding unit 36 codes the scrambled input data according to the first enable signal and the fixed clock signal therefore makes coding unit 36 results in a coding data in the same time. In the mean while, coding unit 36 outputs the coding data to first multiplexer 382 of clipper module 38 according to the fixed clock signal.

Wherein, the coding data comprises a plurality of bit data, and coding unit 36 outputs in parallel the bit data to first multiplexer 382 according to the fixed clock signal, for example: when the data coding rate of clipper module 38 is ¾, make coding unit 36 code the input data into a plurality of bit data and output in parallel the bit data to first multiplexer 382 from coding unit 36, wherein, the input data is 3 bit data, the bit data outputted from coding unit 36 is 3×3 bit data. First multiplexer 382 selects and outputs the 4 bit data of the bit data as an output data according to the selecting signal of control circuit 32, and output in sequence the output data to first latch-up circuit 384; first latch-up circuit 384 is the output data outputted from first multiplexer 382 and output the output data according to the fixed clock signal. The operating methods of control circuit 32, coding unit 36 and clipper module 38 are shown ad FIG. 5 and FIG. 6, which corresponds to different first enable signal and selecting signal according to different data transferring rates in order to induce coding unit 36 output the coding data to first multiplexer 382 of clipper module 38, and induce first multiplexer 382 select and output the partial bit data of the coding data as the output data to firs latch-up circuit 384.

With reference to FIG. 4A, the preferred embodiment of the present invention, as show in the figure that the clipper circuit of present invention comprises control circuit 32, which processes the synchronous control by the data transferring rate and the fixed clock signal for agitating the input data, coding the input data, selecting and outputting the coding data as the output data and synchronous output the output data in the same time. In the present embodiment, the data dealing method of the clipper circuit is making the input data of coding unit 36 as a 3 bit data and the output data of clipper module 38 as a 4 bit data by first enable signal 38 and the selecting signal of control circuit 32, which comprises the data coding rate of ¾ and the corresponding data transferring rate of 200 MHz or 400 MHz. Wherein, the input data is a three bit data from X0 to X2. Coding unit 36 codes the input data X0 as bit data A0, bit data B0 and bit data C0 of the coding data, Coding unit 36 codes the input data X1 as bit data A1, bit data B1 and bit data C1 of the coding data, Coding unit 36 codes the input data X2 as bit data A2, bit data B2 and bit data C2 of the coding data.

As shown in FIG. 4B, the flowchart of one preferred embodiment of input data and output data of present invention. Clipper module 38 selects and outputs the coding data as a 4 bit output data, wherein the bit data selected and outputted by clipper module 38 are bit data A0, bit data B0, bit data C1 and bit data C2 of the coding data to clipper module 38. When first enable signal is in first clock cycle enable, it is able to make coding unit 36 output bit data A0 to bit data C0 to clipper module 38. When first enable signal is in the second clock cycle disenable, it is unable to make coding unit 36 output data to clipper module 38. When first enable signal is in the third clock cycle enable, it is able to make coding unit 36 output bit data Al to bit data C1 to clipper module 38. When first enable signal is in the fourth clock cycle enable, it is able to make coding unit 36 output bit data A2 to bit data C2 to clipper module 38, wherein the disenable of first enable signal is to provide clipper module 38 select and output one of the bit data, which collects from the former clock cycle.

The selecting signal of clipper module 38 in the present embodiment comprises a first selecting signal and a second selecting signal, when the first selecting signal and the second selecting signal are 0 and 0 in the first clock cycle, and make clipper module 38 select and output bit data A0, when the first selecting signal and the second selecting signal are 1 and 0 in the second clock cycle, and make clipper module 38 select and output bit data B0, when the first selecting signal and the second selecting signal are 0 and 1 in the third clock cycle, and make clipper module 38 select and output bit data C1, when the first selecting signal and the second selecting signal are 0 and 1, and make clipper module 38 select and output bit data C2.

Although the present invention has been explained in relation to its preferred embodiment, it is to be understood that many other possible modifications and variations can be made without departing from the spirit and scope of the invention as hereinafter claimed.

What is claimed is:

1. A transceiver puncture circuit of wireless communication system comprising:
a control circuit, which bases on a fixed clock signal and transfer a data transferring rate of an input data in order to result a first enable signal and a selecting signal;
a puncture module, which couples to a coding unit of said transceiver and said control circuit, said coding unit results in a coding data to said puncture module according to said first enable signal and said fixed clock signal, said coding data comprises a plurality of bit data, said puncture module selects some partial bit data of said bit data as a output data according to said selecting signal, and outputs said output data bases on said fixed clock signal.

2. The puncture circuit of claim 1, wherein said puncture module comprises:
a first multiplexer, which selects said partial bit data as said output data according to said selecting signal; and
a latch-up circuit, which is coupled to said first multiplexer, said first latch-up circuit latches said output data, and outputs said output data according to said fixed clock signal.

3. The puncture circuit of claim 2, wherein said first latch-up circuit is a flip-flop.

4. The puncture circuit of claim 1, wherein said control circuit comprises:
an enable control circuit, which results in said first enable signal to said coding unit according to said fixed clock signal and said data transferring rate; and
a selecting control circuit, which results in said selecting signal to said puncture module according to said fixed clock signal and said data transferring rate.

5. The puncture circuit of claim 4, wherein said enable control circuit comprises:
a first saving module, which saves a plurality of first control signals, said first control signals respectively corresponds to different said data transferring rates;
a second multiplexer, which selects and outputs corresponding said first control signal from said first saving module according to said data transferring rate.
a second latch-up circuit, which latches said first control signal outputted from said second multiplexer, and outputs said first control signal according to said fixed clock signal; and
a third latch-up circuit, which latches said first control signal outputted from said second latch-up circuit and outputs said first control signal as said first enable signal according to said fixed clock signal and said first enable signal transfers to said coding unit.

6. The puncture circuit of claim 5, wherein said second latch-up circuit and said third latch-up circuit are flip-flops.

7. The puncture circuit of claim 4, wherein said selecting control circuit comprises:
a second saving module, which saves a plurality of second control signals, said second control signals respectively corresponds to different said data transferring rates;
a third multiplexer, which selects and outputs corresponding said second control signal from said second saving module according to said data transferring rate.
a fourth latch-up circuit, which latches said second control signal outputted from said third multiplexer, and outputs said second control signal according to said fixed clock signal; and
a fifth latch-up circuit, which latches said second control signal outputted from said fourth latch-up circuit, and outputs said second control signal as said selecting signal according to said fixed clock signal, and said selecting signal transfers to said puncture module.

8. The puncture circuit of claim 7, wherein said fourth latch-up circuit and said fifth latch-up circuit are flip-flops.

9. The puncture circuit of claim 1, wherein said transceiver device further comprises:
an scrambling unit, which couples to said control circuit and said coding unit, said control circuit results in a second enable signal to said scrambling unit according to said fixed clock signal and said data transferring rate, said scrambling unit scrambles said input date according to said second enable signal and transfers scrambled said input date to said coding unit.

10. The puncture circuit of claim 9, wherein said second enable signal differs from said first enable signal in one clock cycle.

11. The puncture circuit of claim 9, wherein said control circuit comprises:
an enable control circuit, which results in said first enable signal to said coding unit according to said fixed clock signal and said data transferring rate, and results in said second enable signal to said scrambling unit; and
a selecting control circuit, which results in said selecting signal to said puncture module according to said fixed clock signal and said data transferring rate.

12. The puncture circuit of claim 11, wherein said enable control circuit comprises:
a first saving module, which saves a plurality of first control signals, said first control signals respectively corresponds to different said data transferring rates;
a second multiplexer, which selects and outputs said corresponding first control signal according to said data transferring rate from said first saving module.
a second latch-up circuit, which latches said first control signal outputted from said second multiplexer, and outputs said first control signal as said second enable signal according to said fixed clock signal and said second enable signal transfers to said scrambling unit; and
a third latch-up circuit, which latches said second enable signal outputted from said second latch-up circuit, and outputs said second enable signal as said first enable signal according to said fixed clock signal, and said first enable signal transfers to said coding unit.

13. The puncture circuit of claim 12, wherein said second latch-up circuit and said third latch-up circuit are flip-flops.

14. The puncture circuit of claim 11, wherein said selecting control circuit comprises:
a second saving module, which saves a plurality of second control signals, said second control signals respectively corresponds to different said data transferring rates;
a third multiplexer, which selects and outputs corresponding said second control signal according to said data transferring rate from said second saving module.
a fourth latch-up circuit, which latches said second control signal outputted from said third multiplexer, and outputs said second control signal according to said fixed clock signal; and
a fifth latch-up circuit, which latches said second control signal outputted from said fourth latch-up circuit, and outputs said second control signal as said selecting signal according to said fixed clock signal, and said selecting signal transfers to said puncture module.

15. The puncture circuit of claim 14, wherein said fourth latch-up circuit and said fifth latch-up circuit are flip-flops.
